(19) United States
(12) Patent Application Publication
(10) Pub. No.: US 2021/0114552 A1
(43) Pub. Date: Apr. 22, 2021

(54) APPARATUS FOR DETECTING A PROPER WEARING STATUS OF A SAFETY BELT

(71) Applicant: AUDI AG, 85045 Ingolstadt (DE)

(72) Inventors: MAXIMILIAN TURNWALD, Ingolstadt (DE); CHRISTIAN EWALD, Ingolstadt (DE); KATHARINA KUNTH, Ingolstadt (DE); WOLFGANG MICHALKE, Ingolstadt (DE); PATRICIA STADICK, München (DE); JOACHIM SCHEEF, Buxheim (DE)

(73) Assignee: AUDI AG, 85045 Ingolstadt (DE)

(21) Appl. No.: 16/463,654

(22) PCT Filed: Nov. 23, 2017
(86) PCT No.: PCT/EP2017/001365

§ 371 Date: May 23, 2019

(30) Foreign Application Priority Data
Nov. 25, 2016 (DE) 10 2016 122 806.0

(51) Int. Cl. B60R 22/48; B60R 11/02; G01R 27/26; G01S 11/14; H04R 1/08; G10K 13/00; G10L 25/51

(52) U.S. Cl. CPC B60R 22/48; B60R 11/0247; G01R 27/26; G01S 11/14; H04R 2499/13; G10K 13/00; G10L 25/51; B60R 2022/4808; B60R 2022/485; H04R 1/08

(57) ABSTRACT

Apparatus for detecting a proper wearing status of a safety belt of a safety belt assembly in a motor vehicle includes a sensor device which is at least partially disposed in or on the safety belt and configured to output a sensor value as a function of a dependency on a disposition of the safety belt. An evaluation device determines in response to the sensor value output by the sensor device, whether an occupant of the motor vehicle properly wears the safety belt.

The invention relates to an apparatus for detecting a proper wearing status of a safety belt of a safety belt assembly in a motor vehicle.

It is generally known that an occupant in a vehicle, especially a motor vehicle, is subject to particularly low risk of injury if a safety belt assembly is used properly in the event of an accident. To ensure that every occupant of the motor vehicle properly uses the safety belt assembly as much as possible, devices are used in modern motor vehicles to monitor whether an occupant of the motor vehicle is properly using the safety belt assembly. Still, some occupants of the motor vehicle negate such devices, partly for convenience and partly for other reasons, in order not to use the safety belt assembly. Therefore, devices are to be developed that reliably enable to determine whether a safety belt assembly is being properly used by the respective occupant.

From the prior art, in particular from the production of series vehicles, monitoring and/or control devices to determine a proper use of a safety belt assembly are already well known. Document U.S. Pat. No. 4,885,566 discloses, for example, a safety belt assembly with a belt electrode and a seat electrode, between which an electric field is established, which passes through at least part of a seat occupant. Further provided is a capacitance measuring unit which detects the capacitance formed between the belt electrode and the seat electrode. The capacitance measuring unit is connected to a monitoring unit, which determines on the basis of a particularly low or particularly high capacity, whether or not a belt is disposed around a seat occupant.

The drawback here is the presence of a further electrical component in the vehicle seat. Many documents are known from the prior art that use optical recognition. Document DE 101 42 792 A1 discloses an image processing system for detecting whether a safety belt is worn by a seat occupant as intended.

The disadvantage here is that a garment that is worn by the seat occupant may have a pattern which may be confused by the image processing system with the safety belt.

Object of the present invention is therefore to detect as reliably as possible a proper use of a safety belt assembly in a motor vehicle.

This object is achieved in accordance with the invention by an apparatus and a method having the features of the independent patent claims. Advantageous configurations with suitable refinements of the invention are set forth in the remaining patent claims.

According to the invention, provision is made for an apparatus for detecting a proper wearing status of a safety belt of a safety belt assembly in a motor vehicle, which apparatus includes a sensor device arranged at least partially in or on the safety belt and configured to output at least one sensor value which has a dependency on the disposition of the safety belt, and an evaluation device configured to determine on the basis on the sensor value output by the sensor device, whether an occupant of the motor vehicle properly wears the safety belt.

The safety belt assembly includes, in addition to the safety belt, which is normally designed to date as a three-point belt with automatic wind-up mechanism, a variety of other systems, for example an electric belt tensioner, a pyrotechnic belt tensioner or a device for reducing slack. Associated to the safety belt are a safety belt webbing that is at least partly wound on a drum of the automatic wind-up mechanism, a lower outer attachment point, an upper outer attachment point, and an inner attachment point. The inner attachment point is usually formed on the vehicle side as a belt buckle, which is configured to receive a buckle tongue arranged on the safety belt webbing. The safety belt is worn properly, i.e. a proper wearing status of the safety belt is realized, when the occupant sits in the vehicle in a vehicle seat, the safety belt webbing is disposed on a front body side of the occupant around the occupant, and the buckle tongue is locked in the buckle. A portion of the safety belt webbing that extends between the upper outer attachment point and the inner attachment point at a proper wearing status is referred to as a chest belt, and another portion of the safety belt webbing that extends between the inner attachment point and the lower outer attachment point at a proper wearing status is referred to as lap belt.

The sensor device which is at least partially disposed in or on the safety belt may, for example, be formed as a switch which is arranged in the belt buckle. Depending on whether or not the buckle tongue is locked in the belt buckle, a circuit in which the switch is disposed, is closed or interrupted. The switch thus outputs a sensor value which is generated in response to the disposition of the safety belt and can be evaluated by the evaluation device. The evaluation device can be designed, for example, as an electronic unit which is capable of outputting a warning signal when the circuit is interrupted, i.e. the buckle tongue is not locked in the belt buckle.

As a result, an apparatus is provided which reliably detects a proper use of a safety belt assembly in a motor vehicle.

In a further embodiment according to the invention, the sensor device includes a capacitor with two electrodes, with the one electrode being arranged in or on the safety belt and the other electrode being designed in the form of a heating wire arrangement of a seat heater, with the evaluation device being configured to determine in response to a status value measured on the capacitor as to whether the occupant has fastened the safety belt as intended. In other words, electrically conductive elements which form the one electrode of the capacitor can be arranged on and/or in the safety belt webbing. For example, a plurality of metallic fibers that are in contact with one another may be woven into a fabric of the safety belt webbing, or a metallic coating may be applied onto the fabric of the safety belt webbing. Such a belt-side electrode can be arranged on the lap belt and/or the chest belt. The other electrode of the capacitor is disposed in a vehicle seat and is formed by the seat heating mat. Such a seat heating mat can be arranged in a seat cushion of the vehicle seat and/or in a backrest of the vehicle seat. The belt-side electrodes are associated to a respective seat-side electrode, i.e. the belt electrode of the chest belt is associated to the electrode or seat heating mat in the backrest of the vehicle seat and the belt electrode of the lap belt is associated to the electrode or seat heating mat of the seat cushion of the vehicle seat. Furthermore, the electrodes are respectively connected to the evaluation unit, so that the evaluation unit is able to determine a capacitance of the capacitor. The capacitance of the capacitor depends on a material between the electrode arranged on the safety belt webbing and the electrode arranged in the vehicle seat. This means that the capacitance assumes a first value, when the safety belt webbing is not worn properly, i.e. as intended. For example, the buckle tongue may have been locked in the belt buckle with no occupant sitting in the vehicle seat. This indicates the presence of air between the respectively associated electrodes. The capacitance assumes a second value that is different from the first value, when the safety belt webbing is worn properly, i.e. as intended. This means that the occupant is positioned between the electrode arranged on the safety belt and the electrode arranged in the vehicle seat, with the buckle tongue being locked in the belt buckle. The evaluation device may include, for example, a capacitance measuring device, so that the evaluation device is able to unambiguously and reliably determine whether the occupant seated in the vehicle seat wears the safety belt as intended, i.e. to determine whether the safety belt webbing is disposed on a front side of the occupant's body, or between the vehicle seat and the occupant.

The advantage here is that the seat heating mat in the motor vehicle has a dual functionality by having the seat heating mat form an electrode of the capacitor. As a result, the apparatus can be produced particularly cost-effectively and without additional work steps.

Furthermore, it has proven to be advantageous for the sensor device to include at least one microphone which is arranged on the safety belt and configured to output a microphone signal corresponding to at least one detected sound signal, wherein the evaluation device is configured to determine on the basis of the microphone signal, whether the occupant properly wears the safety belt. The microphone which is arranged on the safety belt, in particular on the safety belt webbing, may for example be designed as a belt microphone which, for example, is part of a vehicle-side hands-free system. The microphone is configured to pick up at least one sound signal generated in the vicinity of the microphone and to output a microphone signal corresponding to the sound signal. Because the microphone is connected to the evaluation device, the evaluation device is able to determine on the basis of characteristics of the microphone signal whether the occupant in the motor vehicle has fastened the safety belt as intended.

This embodiment affords the advantage that the belt microphone arranged on the safety belt has a dual functionality so that the device can be realized in a particularly cost-efficient manner.

A further embodiment of the invention provides that the sound signal comprises an ambient noise and/or a noise of the motor vehicle. In other words, the sound signal can be generated by the motor vehicle. For example, noise generated by an engine of the motor vehicle and penetrating into the interior of the motor vehicle, forms the sound signal. In addition, the sound signal can be generated, for example, in response to a rolling sound of the tires of the motor vehicle during travel.

In this configuration, the use of a separate sound source is omitted, so that the apparatus can be realized particularly cost-effectively.

In a further advantageous embodiment of the invention, provision is made for at least one loudspeaker of the motor vehicle to generate the sound signal. In this case, the loudspeaker may, for example, be part of an infotainment system of the motor vehicle. As an alternative or in addition, the loudspeaker may also be configured as a separate loudspeaker which is associated with the apparatus. The sound signal may be formed as a tone or as a mixture of tones comprising at least two tones of different frequencies.

Because a loudspeaker of the motor vehicle is used to generate the sound signal, there are a variety of ways to implement the detection of the correct wearing status of the safety belt by the apparatus in a particularly reliable manner.

According to a further advantageous embodiment of the invention, provision is made for the evaluation device to determine on the basis of a measurement of the elapsed time of the sound signal from the loudspeaker to the microphone, whether the occupant has put on the safety belt as intended. In other words, the loudspeaker is used to generate the sound signal at a first time instance. The sound signal propagates in the form of at least one wave through the air and, i.a. in a direction of the microphone, with the wave of the sound signal impinging on the belt microphone at a second time instance that is different from the first time instance. Thus, a period elapses between the first time instance (generating the sound signal) and the second time instance (reception of the sound signal by the microphone) and is referred to as the elapsed time of the sound signal. On the basis of this elapsed time, the evaluation device can determine at which distance the microphone or belt microphone is arranged from the loudspeaker at the second time instance. Thus, the evaluation device is able to determine whether the microphone, i.e. the safety belt webbing, is sufficiently close to the loudspeaker in order for the occupant of the vehicle to properly wear it. When the evaluation device determines that the microphone, i.e. the safety belt webbing, is arranged too far away from the loudspeaker, the occupant evidently has not put on the safety belt as intended.

In this advantageous embodiment, the position of a safety belt in a motor vehicle can thus be determined particularly accurately.

In a further embodiment of the present invention, provision is made for the loudspeaker to be controlled in such a way that the sound signal is transmitted cyclically. Cyclical, i.e. recurring sending of the sound signal from the loudspeaker, affords the advantage that the correct wearing status of the safety belt around the occupant can be checked repeatedly. This means that it can be checked whether the occupant has put on the safety belt as intended and whether the occupant changes the proper wearing status of the safety belt, e.g. unlocks the belt buckle, and stops using the safety belt. Thus, the apparatus cannot be bypassed, for example when the occupant buckles up properly when travel with the motor vehicle commences and after a certain time, for example after the first check of the wearing status has been executed, unbuckles the safety belt again.

Furthermore, it has shown to be advantageous when the sound signal is formed as an ultrasonic signal. Particularly in this case, it is possible that the loudspeaker generating the sound signal is part of an interior monitoring device of an anti-theft alarm system of the motor vehicle. Because the human ear is not capable to perceive sound in the ultrasonic range, in particular when a cyclic monitoring of the belt wearing status is involved, a particularly high comfort is maintained. Furthermore, when using the loudspeaker of the anti-theft alarm system, the need for a separate loudspeaker is eliminated, so that the device can be realized in a particularly cost-efficient manner.

A further embodiment of the invention provides that the evaluation device is configured to determine on the basis of at least a change in a variable that characterizes the sound signal, whether the occupant wears the safety belt as intended. In other words, the evaluation device determines whether, for example, an amplitude of the sound signal has been attenuated for a specific time, for example the elapsed time. When the sound signal is sent in the form of a tone mixture by the loudspeaker, the evaluation device is able to determine whether, e.g., only low-frequency components of the tone mixture arrive at the microphone, i.e. a sound diffraction has occurred. Attenuation and/or sound diffraction generally occur, when obstacles, in particular sound obstacles, are present between the sound source, i.e. the loudspeaker, and the sound receiver, i.e. the microphone. As a result, the evaluation device is able to determine whether an occupant is sitting on the previously fastened belt in order to bypass the apparatus. In this case, the occupant may form the sound barrier as the occupant's upper body at least partially obscures the belt microphone.

This embodiment ensures a particularly reliable detection of a proper wearing status by the apparatus.

The present invention further provides a motor vehicle with an apparatus for detecting a proper wearing status of a safety belt of a safety belt assembly. This motor vehicle offers a particularly high occupant protection, since the apparatus reliably detects the proper use of the safety belt assembly in the motor vehicle.

Furthermore, the present invention provides a method for detecting a proper wearing status of a safety belt of a safety belt assembly in a motor vehicle with the steps of: outputting at least one sensor value as a function of the arrangement of the safety belt by means of a sensor device that is arranged at least partially in or on the safety belt, and determining by an evaluation on the basis of the sensor value output, whether an occupant of the motor vehicle has put on the safety belt as intended. Advantageous configurations of the apparatus according to the invention are to be regarded as advantageous configurations of the method according to the invention, wherein the method in particular includes method steps which are executed by the apparatus.

Further advantages, features and details of the invention will become apparent from the following description of preferred exemplary embodiments and with reference to the drawing. The features and feature combinations mentioned above in the description as well as the features and feature combinations mentioned hereinafter in the description of the figures can be used not only alone but also in combination with one another, without departing from the scope of the invention.

The drawing shows in:

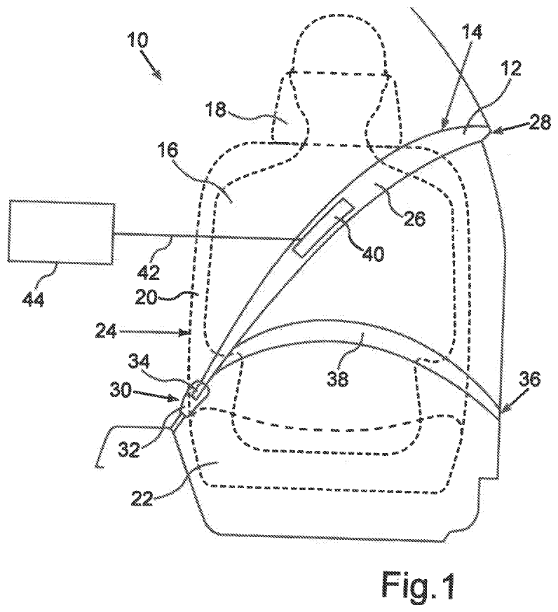

FIG. 1 a schematic view of an apparatus for detecting a proper wearing status of a safety belt of a safety belt assembly in a motor vehicle;

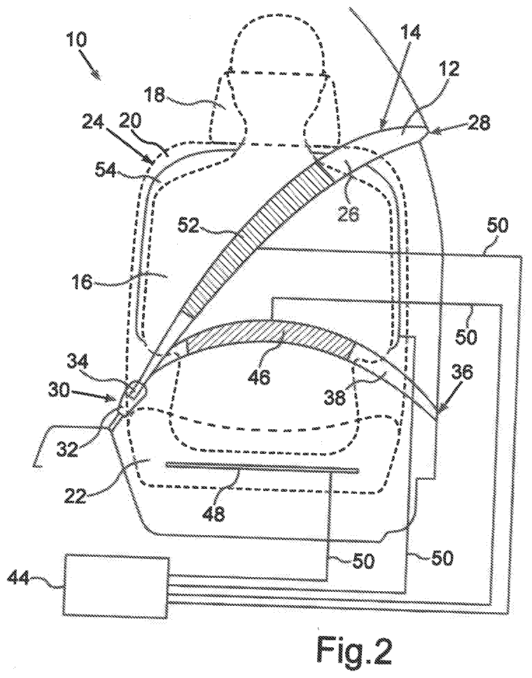

FIG. 2 a schematic view of the apparatus, wherein a principle of capacitive detection is used;

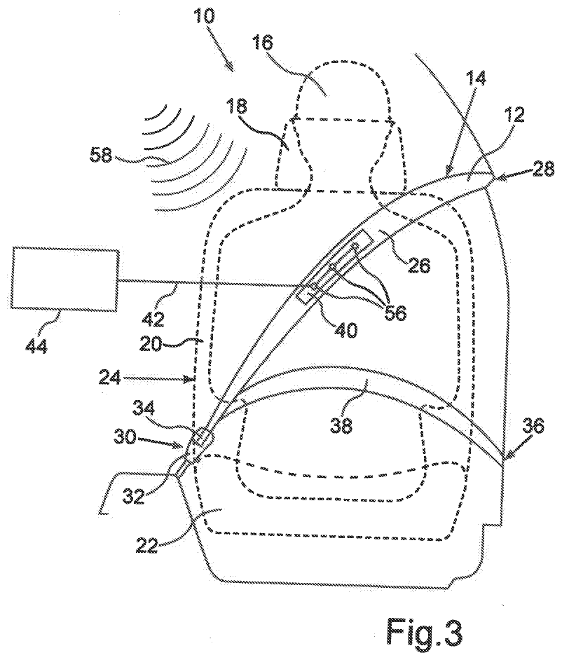

FIG. 3 a schematic view of the apparatus, wherein a principle of acoustic detection is used;

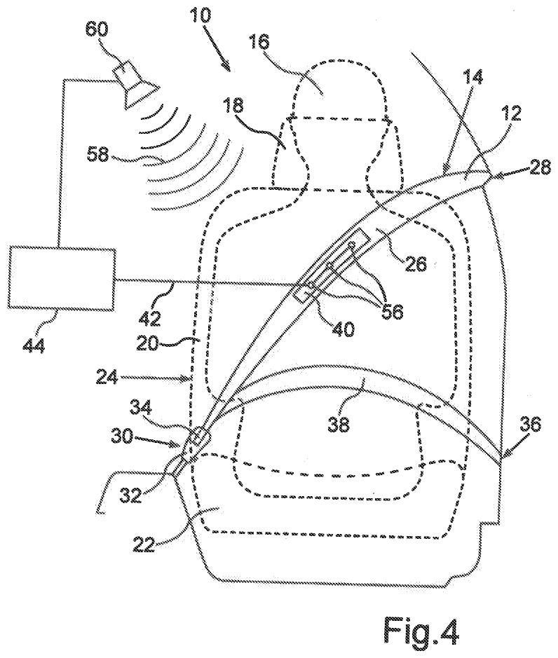

FIG. 4 a schematic view of the apparatus shown in FIG. 3, wherein a loudspeaker is used;

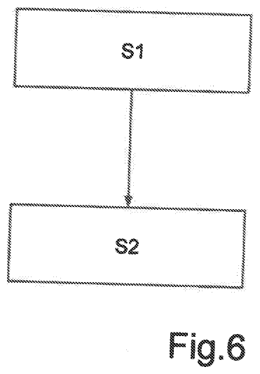

FIG. 5 a schematic view of a motor vehicle with an apparatus for detecting a proper wearing status of a safety belt of a safety belt assembly; and

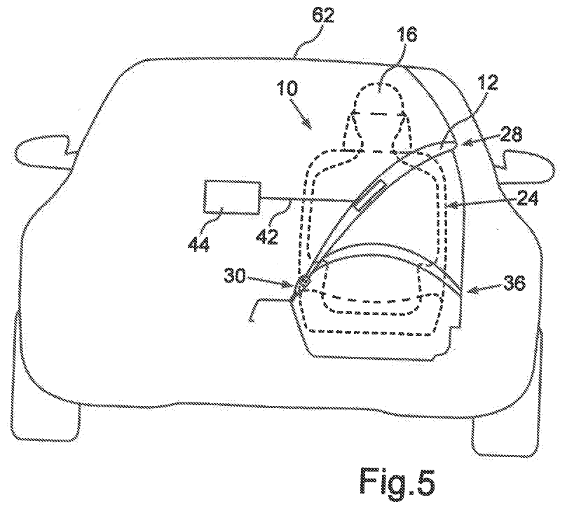

FIG. 6 a flowchart of steps of a method for detecting a proper wearing status of a safety belt of a safety belt assembly in a motor vehicle.

In the figures, identical or functionally identical elements are provided with the same reference numerals.

The apparatus 10 for detecting a proper wearing status of a safety belt 12 of a safety belt assembly 14 in an unillustrated motor vehicle is shown in FIG. 1. FIG. 1 further shows an occupant 16, which sits in a vehicle seat 24 having a headrest 18, a backrest 20 and a seat cushion 22. The safety belt 12 forms a chest belt 26 which extends between an upper outer attachment point 28 and an inner attachment point 30. The inner attachment point 30 is usually designed as a belt buckle 32, in which a buckle tongue 34 is arranged, for example locked. A portion of the safety belt 12, referred to as lap belt 38, extends between the inner attachment point 30 and the lower outer attachment point 36. This arrangement of the safety belt 12 corresponds to a so-called three-point belt, with the belt buckle 32 including a knob, not shown, by means of which the occupant 16 can unlock and remove the buckle tongue 34 from the belt buckle 32 so as to enable a comfortable getting out from the vehicle seat.

Furthermore, FIG. 1 shows a sensor device 40, which is arranged at least partially in or on the safety belt and is connected by a transmission unit 42 to an evaluation unit 44. The sensor device 40 is capable of outputting at least one sensor value which is dependent on a disposition, i.e. positioning of the safety belt. For example, a sensor value for an open belt buckle 32—i.e. the occupant has not locked the buckle tongue 34 in the belt buckle 32—differs from a further sensor value for a closed belt buckle—i.e. the occupant has correctly put on a safety belt 12. The sensor value is provided via the transmission unit 42 to the evaluation device 44. The evaluation device 44 is configured to determine on the basis of the provided sensor value, whether an occupant of the motor vehicle wears the safety belt as intended. The evaluation device 44 may, for example, include means which are able to alert the occupant 16 that the safety belt 12 is not worn as intended. For this purpose, for example, warning signals, for example warning lights and/or warning sounds, can be activated and/or the motor vehicle is prevented from starting.

FIG. 2 shows the apparatus 10, wherein detection of the proper wearing status of the safety belt 12 can be realized through capacitive detection. For this purpose, an electrical capacitor or a device similar to an electrical capacitor is used in the motor vehicle. The first electrode 46 is attached to the lap belt 38, for example. The first electrode 46 may be woven into the lap belt 38 in the form of metallic fibers and/or may be applied to a fabric of the webbing of the safety belt 12 in the form of a metallic coating. A second electrode 48 associated to the first electrode 46 and configured as a heating wire arrangement for a vehicle seat heater is formed in the vehicle seat 24, in particular in the seat cushion 22 of the vehicle seat 24. The electrode 48 and the electrode 48 substantially oppose one another and are each connected to the evaluation device 44 via the transmission unit 42, which is designed as a cable 50, for example. As they oppose one another, the two electrodes 46 and 48 form the capacitor-like arrangement, which has an electrical capacitance. The electrical capacitance, i.e. the sensor value, depends in this embodiment inter alia on the distance between the two electrodes 48 and 46 from each other and on the material being arranged between the two electrodes 46 and 48. Thus, the capacitance of the capacitor-like arrangement as measured by the evaluation device 44 can be used to determine whether the lap belt 38 property extends around a lower body of the occupant 16 and not directly on the surface of the seat cushion 22 between the lower body of the occupant 16 and the seat cushion 22.

As also shown in FIG. 2, as an alternative or In addition, a further capacitor-like arrangement may be used in the apparatus 10 to detect capacitively whether an occupant 16 wears the safety belt 12 as intended. For this purpose, a further electrode 52 can be arranged in and/or on the chest belt 26. A further seat heating mat or electrode 54 may be integrated in the backrest 20 of the vehicle seat 24 to form with the associated electrode 52 a further capacitor-like arrangement. The seat heating mat or electrode 54 and the electrode 52 are each connected to the evaluation device 44 via a cable 50. As the evaluation device 44 measures the electrical capacitance of the capacitor-like arrangement formed by the electrodes 52 and 54, it can be determined whether the safety belt 12 extends on the upper body of the occupant 16 and not on the back of the occupant 16 between the upper body of the occupant 16 and the backrest 20 of the vehicle seat 24. Measuring the electrical capacitance of the capacitor-like arrangements of the apparatus 10 by means of the evaluation device 44 can be established, for example, by applying an alternating voltage to the capacitor-like arrangement and measuring the current flow. Since the electrical capacitance and the current flow in an ΔC circuit are directly proportional to each other, the capacitance of the capacitor-like arrangement can be determined by using simple physical formulas.

FIG. 3 shows the apparatus 10, in which the sensor device 40 can have at least one microphone or belt microphone 56 arranged on the safety belt. The belt microphone 56 is configured to detect a sound signal 58 and to output a microphone signal in correspondence with the sound signal 58. The microphone signal is provided via the transmission unit 42 to the evaluation device 44. The evaluation device 44 is configured to evaluate the microphone signal as to whether the safety belt 12 is disposed as intended around the occupant 16. This means that when the safety belt 12 is disposed as intended around the occupant 16, a first microphone signal is generated by the belt microphone 56 in response to the sound signal 58 and differs from a second microphone signal, which is generated by the belt microphone 56 in response to the sound signal 58 when the safety belt 12 is incorrectly worn or not worn at all by the occupant 16.

The sound signal 58 may include an ambient noise and/or a noise of the motor vehicle. This means that, in particular during travel of the motor vehicle, noises which are generated, for example, by an operation of an engine of the motor vehicle and/or by tires of the motor vehicle rolling on the roadway, penetrate into an interior of the motor vehicle. These sounds that have propagated into the interior of the motor vehicle can be detected by the belt microphone 56 and converted into the microphone signal. When the evaluation device 44 determines that the sounds that have migrated into the interior of the motor vehicle are to be classified as particularly quiet, then the evaluation device 44 determines that the occupant 16 has not property put on the safety belt 12.

FIG. 4 shows the possibility in the apparatus 10 to generate the sound signal 58 by at least one loudspeaker 60 of the motor vehicle. As the sound signal 58 is actively generated by the loudspeaker 60, the evaluation device 44 can implement an elapsed time measurement, involving a measurement of the time that elapses between generation of the sound signal 58 by the loudspeaker 60 until detection of the sound signal 58 by the belt microphone 56. Based on the elapsed time measurement, the evaluation device 44 is able to determine a distance lying between the loudspeaker 60 and the belt microphone 56. As a result, the evaluation device 44 can determine whether the safety belt 12, in particular the chest belt, is being used properly by the occupant 16. When also using a belt microphone 56 on the lap belt 38, the evaluation device 44 is able to determine whether the lap belt 38 is properly used by the occupant 16.

Furthermore, in the apparatus 10, the loudspeaker 60 may be controlled such that the sound signal 58 is outputted cyclically, i.e. recurrently. As a result, a proper wearing status of the safety belt 12 can be checked not only once, for example immediately after having buckled up, but over the entire duration during which the occupant 16 should be buckled up.

Furthermore, the sound signal 58 may be formed as an ultrasonic signal. Because the human ear cannot perceive sound signals in the ultrasonic range, the apparatus 10 can be used in a motor vehicle without adversely affecting comfort for the occupant 16. Furthermore, the sound signal 58 formed as an ultrasonic signal can be generated by the loudspeaker 60, wherein the loudspeaker 60 can be part of an interior monitoring device of an anti-theft alarm system of the motor vehicle for example. It is, however, also conceivable for the loudspeaker 60 to be part of an infotainment system of the vehicle. The belt microphone 56 is tuned to the frequency range in which the loudspeaker 60 generates the sound signal 58, so that the belt microphone 56 is able to detect the sound signal 58 generated by the loudspeaker 60.

Moreover, the evaluation device may be able to determine at least one of the variables that characterize the sound signal 58 and to determine on the basis thereof whether the occupant 16 wears the safety belt 12 as intended. A variable that characterizes the sound signal 58 may be an amplitude or a frequency of the sound signal 58. When the sound signal 58 generated by the loudspeaker 60 encounters an obstacle, a sound signal may reach the belt microphone 56 which sound signal differs in its amplitude and/or frequency from the generated sound signal 58. In other words, the sound signal 58 may be attenuated and/or diffracted before being detected by the belt microphone 56. The evaluation device 44 is configured to determine, based on a diffraction or attenuation of the sound signal 58, whether the occupant 16 wears the safety belt 12 as intended. For example, the sound signal 58 is attenuated before being detectable by the belt microphone 56, when the occupant 16 passes the safety belt 12, in particular the chest belt 26, behind the back of the occupant 16, i.e. between the occupant 16 and the vehicle seat 24. As an alternative or in addition, the sound signal 58 may be attenuated and/or diffracted when the occupant 16 has placed the lap belt 38 directly on the seat cushion 22 of the vehicle seat 24, so that the occupant 16 sits on the lap belt 38.

FIG. 5 illustrates a motor vehicle 62, which includes an apparatus 10 for detecting a proper wearing status of a safety belt 12 of a safety belt assembly.

FIG. 6 shows a method for recognition of a proper wearing status of a safety belt of a safety belt assembly in a motor vehicle. In this method, a first step S1 involves output of at least one sensor value, which is dependent on the safety belt disposition, by means of a sensor device that is arranged at least partially in or on the safety belt, and a second step S2 involves determination by an evaluation device based on the sensor value output as to whether an occupant of the motor vehicle wears the safety belt as intended.

### LIST OF REFERENCE NUMBERS

10 apparatus
12 safety belt
14 safety belt assembly
16 occupant
18 headrest
20 backrest
22 seat cushion
24 vehicle seat
26 chest belt
28 upper outer attachment point
30 inner attachment point
32 belt buckle
34 buckle tongue
36 lower outer attachment point
38 lap belt
40 sensor device
42 transmission unit
44 evaluation unit
48 electrode
48 electrode or seat heating mat
50 cable
52 electrode
54 electrode or seat heating mat
56 microphone
58 sound signal
60 loudspeaker
62 motor vehicle.

1.-11. (canceled)

12. Apparatus for detecting a proper wearing status of a safety belt of a safety belt assembly in a motor vehicle, said apparatus comprising:
a sensor device at least partially disposed in or on the safety belt and configured to output a sensor value as a function of a dependency on a disposition of the safety belt; and
an evaluation device determining in response to the sensor value output by the sensor device, whether an occupant of the motor vehicle properly wears the safety belt.

13. The apparatus of claim 12, wherein the sensor device comprises a capacitor including two electrodes, with one of the two electrodes arranged in or on the safety belt and the other one of the two electrodes forming a heating wire arrangement of a seat heater, said evaluation device determining in response to a state value measured on the capacitor, whether the occupant properly wears the safety belt.

14. The apparatus of claim 12, wherein the sensor device comprises a microphone arranged on the safety belt and configured to output a microphone signal that corresponds to a detected sound signal, said evaluation device determining in response to the microphone signal, whether the occupant properly wears the safety belt.

15. The apparatus of claim 14, wherein the sound signal includes ambient noise and/or noise of the motor vehicle.

16. The apparatus of claim 14, further comprising a loudspeaker configured to generate the sound signal.

17. The apparatus of claim 16, wherein the evaluation device is configured to determine in response to a measurement of an elapsed time of the sound signal from the loudspeaker to the microphone, whether the occupant properly wears the safety belt.

18. The apparatus of claim 16, wherein the loudspeaker is configured to transmit the sound signal cyclically.

19. The apparatus of claim 16, wherein the loudspeaker is configured to output the sound signal as an ultrasonic signal.

20. The apparatus of claim 14, wherein the evaluation device is configured to determine in response to a change in a variable characterizing the sound signal, whether the occupant properly wears the safety belt.

21. A motor vehicle, comprising an apparatus for detecting a proper wearing status of a safety belt of a safety belt assembly, said apparatus comprising a sensor device at least partially disposed in or on the safety belt and configured to output a sensor value as a function of a dependency on a disposition of the safety belt, and an evaluation device determining in response to the sensor value output by the sensor device, whether an occupant of the motor vehicle properly wears the safety belt.

22. The motor vehicle of claim 21, wherein the sensor device comprises a capacitor including two electrodes, with one of the two electrodes arranged in or on the safety belt and the other one of the two electrodes forming a heating wire arrangement of a seat heater, said evaluation device determining in response to a state value measured on the capacitor, whether the occupant properly wears the safety belt.

23. The motor vehicle of claim 21, wherein the sensor device comprises a microphone arranged on the safety belt and configured to output a microphone signal that corresponds to a detected sound signal, said evaluation device determining in response to the microphone signal, whether the occupant properly wears the safety belt.

24. The motor vehicle of claim 23, wherein the sound signal includes ambient noise and/or noise of the motor vehicle.

25. The motor vehicle of claim 23, further comprising a loudspeaker configured to generate the sound signal.

26. The motor vehicle of claim 25, wherein the evaluation device is configured to determine in response to a measurement of an elapsed time of the sound signal from the loudspeaker to the microphone, whether the occupant properly wears the safety belt.

27. The motor vehicle of claim 25, wherein the loudspeaker is configured to transmit the sound signal cyclically.

28. The motor vehicle of claim 25, wherein the loudspeaker is configured to output the sound signal as an ultrasonic signal.

29. The motor vehicle of claim 23, wherein the evaluation device is configured to determine in response to a change in a variable characterizing the sound signal, whether the occupant properly wears the safety belt.

30. A method for detecting a proper wearing status of a safety belt of a safety belt assembly in a motor vehicle, said method comprising:
outputting a sensor value as a function of a disposition of the safety belt by a sensor device which is at least partially disposed in or on the safety belt; and
determining by an evaluation device in response to the sensor value output, whether an occupant of the motor vehicle property wears the safety belt.
